(19) United States
(12) Patent Application Publication
(10) Pub. No.: US 2006/0291173 A1
(43) Pub. Date: Dec. 28, 2006

(54) Printed circuit board with embedded electronic components

(75) Inventors: Suk-Hyeon Cho, Gyeonggi-do (KR); Chang-Sup Ryu, Daejeon (KR); Han-Seo Cho, Daejeon (KR); Sang-Jin Baek, Chungcheongbuk-do (KR); Jin-Yong Ahn, Daejeon (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/452,322

(22) Filed: Jun. 14, 2006

(30) Foreign Application Priority Data
Jun. 22, 2005 (KR) 10-2005-0054035

(51) Int. Cl. H05K 1/18

(52) U.S. Cl. 361/760; 361/782; 361/783; 174/260; 29/832

(57) ABSTRACT

A printed circuit board with embedded electronic components and fabrication method thereof are disclosed. The printed circuit board with embedded electronic components having outer electrodes comprising a substrate on which insertion holes are formed for containing the electronic components, a filler for filling the gap between the electronic component and the insertion hole to secure the electronic components, and attachment layers laminated onto the substrate in contact with the electrodes, with circuits formed on the attachment layers, may provide superior electrical reliability, as the outer electrodes of the electronic components are in contact with the attachment layers, and may reduce fabrication cost and time, as it is not necessary to form via holes.

### CROSS-REFERENCE TO RELATED APPLICATIONS

This application claims the benefit of Korean Patent Application No. 2005-54035 filed with the Korea Industrial Property Office on Jun. 22, 2005, the disclosure of which is incorporated herein by reference.

### BACKGROUND

1. Technical Field

The present invention relates to a printed circuit board with embedded electronic components and a fabrication method thereof.

2. Description of the Related Art

In response to demands for electronic devices with greater capabilities and smaller sizes, the recent trend is towards more densified and more miniaturized electronic components. The demand is thus increasing for small printed circuit boards which allow high-density mounting of electronic components. Accordingly, the multilayer circuit board is being developed, which provides electrical connection between wiring or between wiring and electrical components formed on different layers through via holes. The multilayer circuit board can not only reduce the wiring that interconnects electronic components, but can also provide high-density wiring. This has the advantages of increasing the surface area of the printed circuit board, as well as providing superior electrical characteristics.

FIG. 1 is a cross-sectional view of a conventional printed circuit board having a mounted electronic component. With the conventional printed circuit board 10, an electronic component 14 is mounted on the surface of a wiring layer 11, an insulation layer 12 is laminated afterwards, and then an insulation layer 11 is again laminated on top. Several via holes 13 are formed for the electrical connection between wiring layers 11 and between a wiring layer 11 and the electronic component 14.

The via holes 13 are created by forming an insulation layer 12, making perforations, and then coating the insides of the perforations with a metal. However, such via holes 13 require a complicated fabrication process, and entail many limitations in designing the wiring layers 11.

Further, while the reliability of the via holes 13 is crucial in providing a stable printed circuit board, stresses occur on the via holes 13 due to heat generated during the fabrication of the printed circuit board and due to the differences in heat expansion with the insulation layers 12 according to the operating environment, and such stresses become a cause of diminished connection reliability of the via holes 13.

### SUMMARY

The present invention has been devised to resolve the foregoing problems, and an aspect of the invention provides a printed circuit board with embedded electronic components, which does not require via holes.

Additional aspects and advantages of the present general inventive concept will be set forth in part in the description which follows and, in part, will be obvious from the description, or may be learned by practice of the general inventive concept.

To achieve the foregoing objectives, the present invention may be implemented in such embodiments as set forth below.

A printed circuit board with embedded electronic components having outer electrodes, according to one embodiment of the invention, comprises a substrate on which insertion holes are formed for containing the electronic components, a filler for filling the gap between the electronic component and the insertion hole to secure the electronic components, and attachment layers laminated onto the substrate in contact with the electrodes, with circuits formed on the attachment layers.

By virtue of this composition, the printed circuit board with embedded electronic components based on the present invention does not require via holes, since the attachment layers and the electrodes of the electronic components are in direct contact with each other. Thus, not only may the reliability of the electrical connection of the electronic components be increased, but also the fabrication cost and time may be reduced as well.

In another embodiment of the invention, the substrate may have substantially the same thickness as that of the electronic components. A first electrode ma be formed on one surface, and a second electrode may be formed on the other surface of the electronic component. The attachment layer may be formed of a first attachment layer in contact with the first electrode and a second attachment layer in contact with the second electrode. In another embodiment of the invention, two or more electrodes are formed on one surface of the electronic component, and the attachment layers may also include an attachment layer in contact with the electrodes.

The substrate may be formed of a copper clad laminate. The electronic components may be active elements as well as passive elements, where both active elements and passive elements may be mounted together. Also, the printed circuit board may be laminated in two or more layers.

A method of fabricating a printed circuit board with embedded electronic components having outer electrodes, according to an embodiment of the present invention comprises forming insertion holes for containing the electronic components on a substrate, inserting and securing the electronic components in the insertion holes, filling the gaps between the insertion holes and the electronic components, forming an attachment layer in contact with the electrode on at least one surface of the substrate, and forming circuits on the attachment layer.

Securing the electronic components in the insertion holes may be achieved by attaching an adhesion sheet on a surface of the substrate or by using adhesive. The adhesion sheet or adhesive may be formed of a material that loses its adhesion with heat or UV radiation.

It may be preferable to further include a desmearing process of removing smears that occur during the forming of the insertion holes.

Preferably, filling the gaps with the filler may be performed using a vacuum printer to prevent the occurrence of bubbles in the insertion holes. The substrate may be a copper clad laminate forming or including an insulation layer. The electronic components may be passive elements and/or active elements.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view of a conventional printed circuit board with an embedded electronic component.

FIG. 2 is a cross-sectional view of a printed circuit board with an embedded electronic component having outer electrodes in an up/down arrangement, according to an embodiment of the invention.

FIG. 3 is a cross-sectional view of a printed circuit board with an embedded electronic component, in which the substrate is a copper clad laminate, according to another embodiment of the invention.

FIG. 4 is a cross-sectional view of a printed circuit board with an embedded electronic component having outer electrodes on only one surface of the electronic component, according to yet another embodiment of the invention.

FIG. 5 is a cross-sectional view of a printed circuit board with an embedded electronic component, in which the substrate is a copper clad laminate, according to still another embodiment of the invention.

FIG. 6a is a schematic diagram illustrating an example of outer electrodes formed on one surface of an electronic component.

FIG. 6b is a schematic diagram illustrating another example of outer electrodes formed on one surface of an electronic component.

FIG. 7 is a flowchart illustrating a fabrication method of a printed circuit board with embedded electronic components, according to an embodiment of the invention.

FIG. 8 is a cross-sectional view illustrating an insertion hole formed on a substrate for containing an electronic component.

FIG. 9a is a cross-sectional view illustrating the operation of securing an electronic component using an adhesion sheet.

FIG. 9b is a cross-sectional view illustrating the operation of securing an electronic component by applying an adhesive.

FIG. 10 is a cross-sectional view after the gap between an insertion hole and an electronic component has been filled.

FIG. 11 is a cross-sectional view after attachment layers in contact with the electrodes of the electronic component have been laminated onto both surfaces of the substrate.

FIG. 12 is a cross-sectional view after circuits have been formed on both surfaces of the attachment layers.

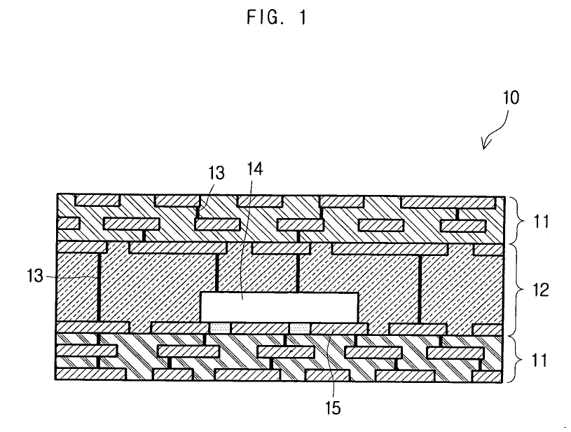

### DETAILED DESCRIPTION

Embodiments of the invention will now be described in detail with reference to the accompanying drawings, wherein those elements are rendered the same reference numeral that are the same or are in correspondence regardless of the figure number, and redundant explanations are omitted.

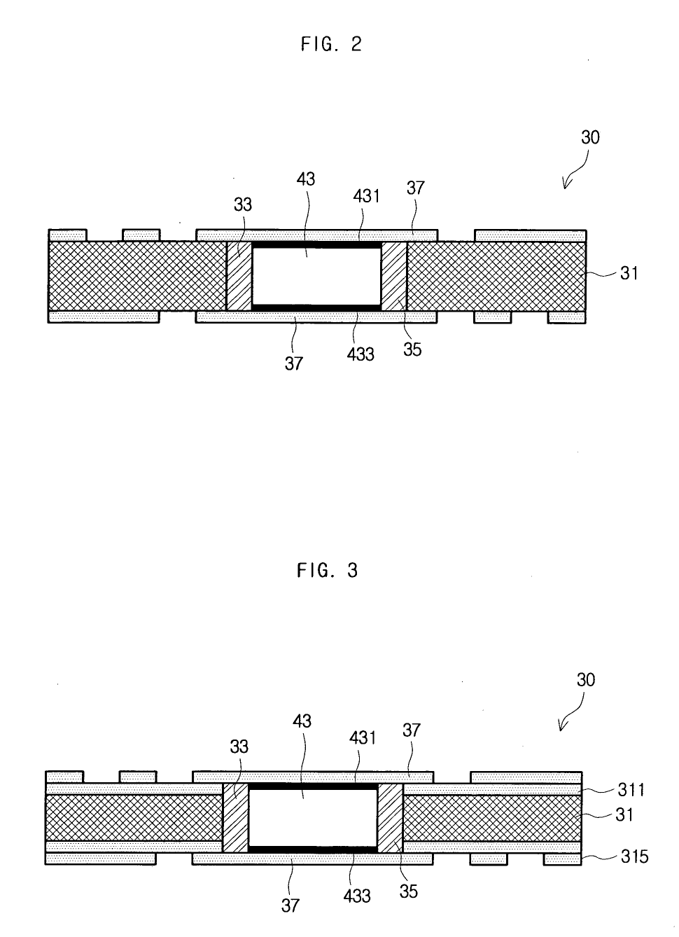

FIG. 2 is a cross-sectional view of a printed circuit board with an embedded electronic component according to an embodiment of the invention. Referring to FIG. 2, a printed circuit board 30 with an embedded electronic component comprises a substrate 31 having an insertion hole 33 and having substantially the same thickness as that of the electronic component 43, a filler 35 for filling the insertion hole 33, and attachment layers 37 laminated onto one or both surfaces of the substrate 31.

The substrate 31 is an insulation layer positioned between the attachment layers 37. The substrate 31 may be formed as a layer in which an inorganic filler is dispersed in a resin compound, including a thermosetting resin. Preferably, the thermosetting resin may include at least one of an epoxy resin, phenol resin, or isocyanate resin. This is because a thermosetting resin is superior in mechanical strength and heat resistance. Also, a variety of additives, such as a coupler, dispersant, or colorant, may be preferably be included in the resin compound to improve the properties of the substrate 31. For example, a coupler may improve the adhesion between the resin compound and the inorganic filler, and a dispersant may improve the dispersion of the inorganic filler and remove stains in the mixture.

The inorganic filler may be any one of Al2O3, MgO, BN, SiO2, SiC, and Si3N4, etc., or a combination thereof. These materials are superior in terms of heat conductivity, and thus may enhance the heat radiation of the substrate 31.

The insertion hole 33 is perforated in a predetermined position on the substrate 31. Since the electronic component 43 is inserted into the insertion hole 33, the insertion hole 33 is formed to have a size somewhat larger than that of the electronic component 43. Various methods are available for forming the insertion hole 33, such as pressing, drilling, and laser processing, etc. It may be preferable to perform an additional desmearing process of removing smears that occur when using drilling or pressing processes to form the insertion hole 33.

The filler 35 is filled between the electronic component 43 and the insertion hole 33, to secure the electronic component 43. In general, epoxy resin may be used for the filler 35. When applying the filler 35, it may be preferable to prevent the occurrence of bubbles in the insertion hole 33 by using a vacuum printer.

The attachment layers 37 are metal layers laminated onto one or both surfaces of the substrate 31, and are in contact with the outer electrodes 431, 433 of the electronic components 43. The attachment layers 37 may be formed by copper cladding. Since the attachment layers 37 are in direct contact with the electrodes 431, 433 of the electronic component 43, the printed circuit board with embedded electronic components based on the present invention does not require via holes. Therefore, a more flexible design is possible, as well as reduced fabrication cost and time, when forming circuits on the attachment layer 37, because it is not necessary to consider via holes as in previous art. Moreover, the direct contact between the attachment layers 37 and the electrodes 431, 433 of the electronic component 43 provides a superior electrical reliability. Various circuits may be formed on the attachment layers 37 by circuit printing processes.

The electronic component 43 has substantially the same thickness as that of the substrate 31. Also, on the upper and lower surfaces are formed the first electrode 431 and the second electrode 433, respectively. The first electrode 431 and the second electrode 433 are in contact with the attachment layers 37. The electronic component 43 may be an active element, such as a transistor, IC, and LSI, etc., or may be a passive element, such as a resistor, condenser, and inductor.

FIG. 3 is a cross-sectional view of a printed circuit board with an embedded electronic component according to another embodiment of the invention. In this embodiment, the substrate 31 is formed of a copper clad laminate (CCL) 31. An attachment layer 37 is laminated onto each of the upper copper cladding 311 and the lower copper cladding 315, formed respectively on the upper and lower surfaces of the copper clad laminate 31. Circuits are formed on the upper copper cladding 311, lower copper cladding 315, and attachment layers 37 by circuit printing processes.

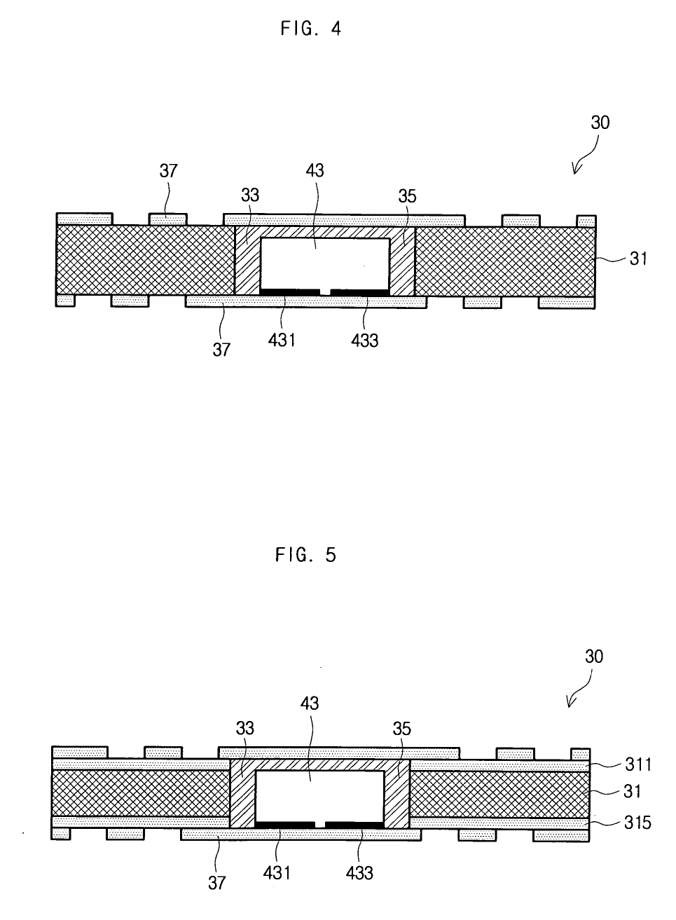

FIG. 4 is a cross-sectional view of a printed circuit board with an embedded electronic component according to another embodiment of the invention. The electronic component 43, as illustrated in FIGS. 4 and 5, has the outer electrodes 431, 433 formed on only one surface. The electrodes 431, 433 are in contact with one attachment layer 37. Here, the thickness of the substrate 31 may be equal to or greater than the thickness of the electronic component 43. The substrate 31 may be formed of a copper clad laminate 31 as in FIG. 5.

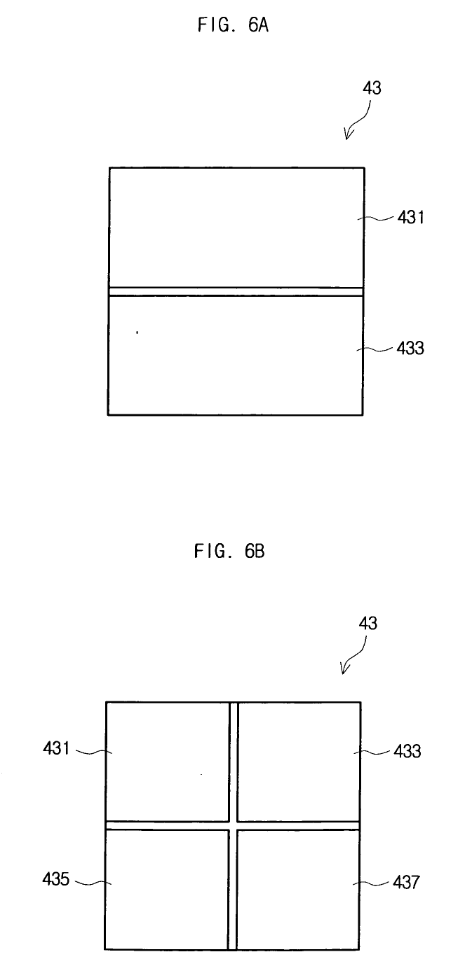

FIG. 6a and FIG. 6b are schematic diagrams illustrating shapes of the outer electrodes of the electronic component 43. Although the electrodes on the exterior of the electronic component 43 may be formed in an up/down arrangement as in FIGS. 2 and 3, a plurality of electrodes may be formed on one surface of the electronic components 43. When the electrodes are formed only on one surface of the electronic component 43, the attachment layer 37 that is in contact with the electrode may be formed on just one surface.

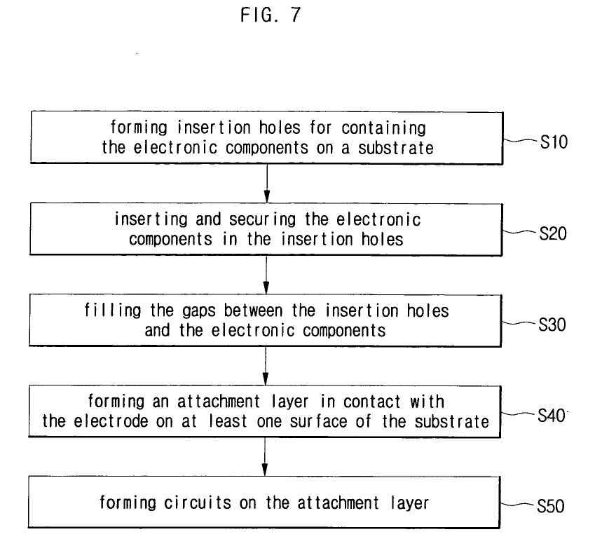

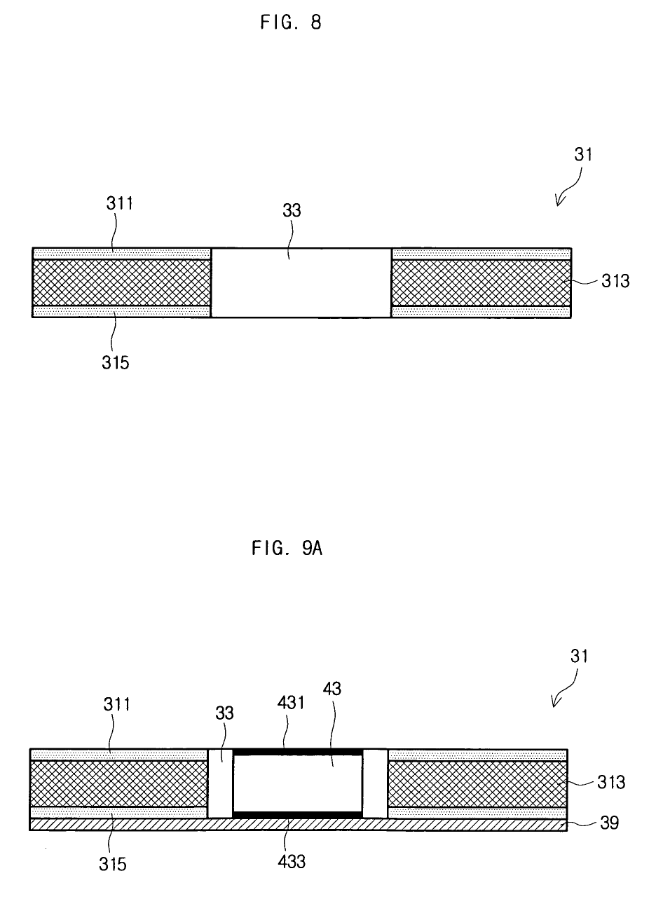

FIG. 7 is a flowchart illustrating a fabrication method of a printed circuit board with embedded electronic components, according to an embodiment of the invention. Referring to FIG. 7, the fabrication method of a printed circuit board with embedded electronic components according to an embodiment of the invention comprises forming insertion holes 33 for containing the electronic components 43 on the substrate 31 (S10), inserting and securing the electronic components 43 in the insertion holes 33 (S20), filling the gaps between the insertion holes 33 and the electronic components 43 (S30), forming an attachment layer 37 in contact with the electrode on each surface of the substrate 31 (S40), and forming circuits on each attachment layer 37 (S50). Hereinafter, operations S10 to S50 are described with reference to FIGS. 8 to 12.

FIG. 8 is a cross-sectional view illustrating the operation S10 of forming the insertion holes 33 on the substrate 31′. The insertion holes 33 are formed by pressing, drilling, or laser processing, etc. It may be preferable to make the sizes of the insertion holes 33 somewhat larger than those of the electronic components 43, to ensure that the electronic components 43 are contained in the insertion holes 33.

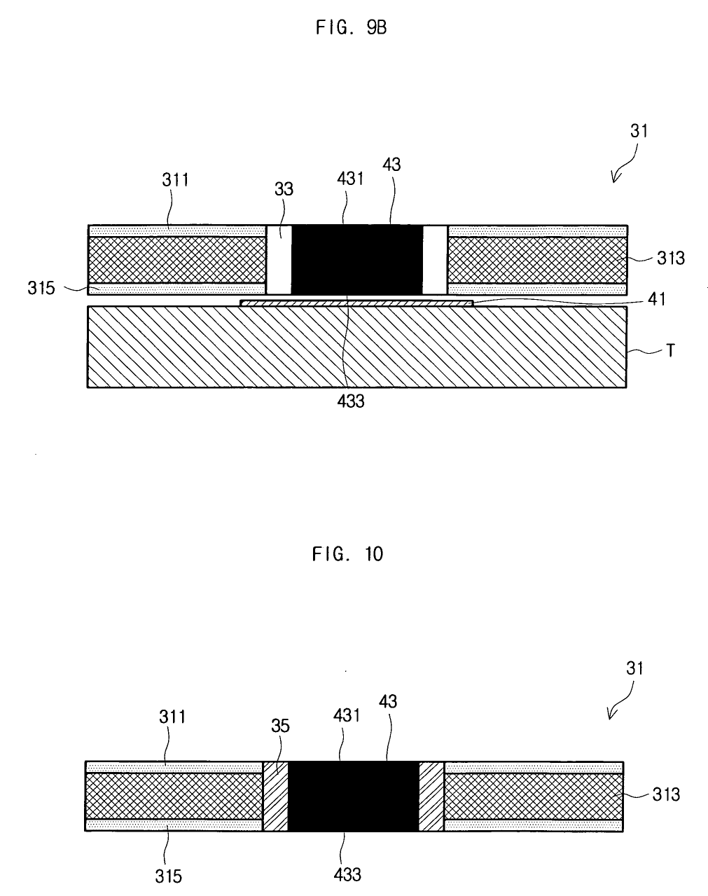

FIG. 9a is a cross-sectional view illustrating an implementation of the operation S20 of securing the electronic components 43 contained in the insertion holes 33. An adhesion sheet 39 is attached to a surface of the substrate 31, and the electronic components 43 are secured within the insertion holes 33 by means of the adhesion sheet 39. Typical double-sided tape may be used for the adhesion sheet 39. The adhesion sheet 39 is exfoliated after applying the filler 35.

FIG. 9b is a cross-sectional view illustrating another implementation of operation S20. First, adhesive 41 is coated on a table (T) in areas somewhat larger than the size of the electronic components 43, and then the substrate 31 and electronic components 43 are positioned in order. Adhesion ink may be used for the adhesive 41. The filler 35 is applied while the electronic components 43 are secured by the adhesive 41, after which portions of the adhesive 41 are removed by means of polishing processes, should the adhesive 41 protrude beyond the surface of the substrate 31 or cover the electrodes of the electronic components 43.

It is preferable that the adhesion sheet 39 or the adhesive 41 lose its adhesion with heat or UV radiation. Thus, the adhesion sheet 39 may readily be detached or the substrate may readily be detached from the table (T) by supplying heat or UV radiation, after applying the filler while the electronic components 43 are secured by the adhesion sheet 39 or the adhesive 41.

FIG. 10 is a cross-sectional view illustrating the operation S30 of filling the gaps between the insertion holes 33 and the electronic components 43. As the insertion holes 33 are filled with the filler 35, such as epoxy resin, etc., the electronic components 43 are secured by the filler 35. The filler 35 may be applied by means of a vacuum printer to prevent the occurrence of bubbles in the insertion holes 33. The filler 35 is generally applied by means of a plugging process.

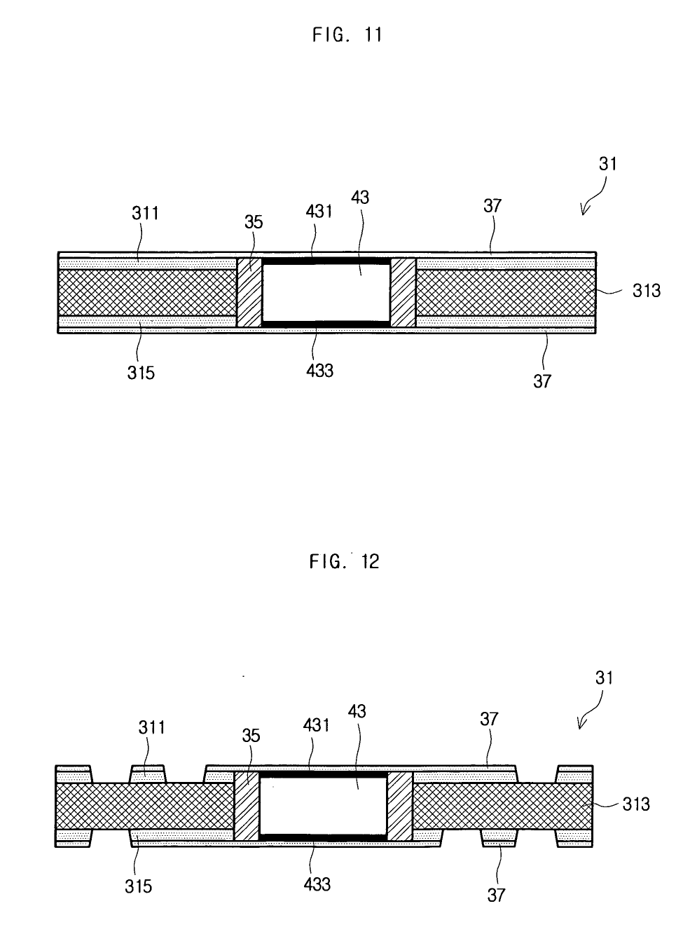

FIG. 11 is a cross-sectional view illustrating the operation S40 of forming attachment layers 37 in contact with the electrodes 431, 433 of the electronic components 43 on each surface of the substrate 31 (S40). As seen in FIG. 11, the attachment layers 37 are laminated onto both sides of the substrate 31 by copper cladding, etc., in contact with the electrodes 431, 433 of the electronic components 43. Of course, when the electrodes are formed on one surface of each electronic component 43 as illustrated in FIGS. 4 and 5, the attachment layer 37 may be formed only on one surface of the substrate 31.

FIG. 12 is a cross-sectional view illustrating the operation S50 of forming circuits on each attachment layer 37. Circuits are formed on each attachment layer 37 on the upper and lower portions of the substrate 31 by typical circuit forming processes. Also, the attachment layer 37 is remained selectively on the portions where the electronic components 43 are embedded to enable electrical connection. A printed circuit board 30 with embedded electronic components thus formed may be laminated in two or more layers.

According to the present invention, the embodiments of which are comprised as set forth above, the following benefits may be obtained.

Since the electronic components are connected by direct contact between the electrodes of the electronic components and the attachment layers, a printed circuit board with embedded electronic components and fabrication method thereof may be obtained which provide superior electrical reliability.

As the present invention does not require via holes, a printed circuit board with embedded electronic components and fabrication method thereof may be obtained with which the fabrication is made easier, with reductions in fabrication cost and time.

Although a few embodiments of the present invention have been shown and described, it will be appreciated by those skilled in the art that changes may be made in these embodiments without departing from the principles and spirit of the invention, the scope of which is defined in the appended claims and their equivalents.

What is claimed is:

1. A printed circuit board with embedded electronic components having outer electrodes, comprising:
a substrate, on which insertion holes are formed for containing the electronic components;
a filler, for filling the gap between the electronic component and the insertion hole to secure the electronic components; and
attachment layers laminated onto the substrate in contact with the electrodes,
wherein circuits are formed on the attachment layers.

2. The printed circuit board with embedded electronic components, as set forth in claim 1, wherein
the substrate has substantially the same thickness as that of the electronic components;
a first electrode is formed on one surface and a second electrode is formed on the other surface of the electronic component; and
the attachment layer is formed of a first attachment layer in contact with the first electrode and a second attachment layer in contact with the second electrode.

3. The printed circuit board with embedded electronic components, as set forth in claim 1, wherein
two or more electrodes are formed on one surface of the electronic component; and
the attachment layers include an attachment layer in contact with the electrodes.

4. The printed circuit board with embedded electronic components, as set forth in any of claims 1 to 3, wherein the substrate is a copper clad laminate.

5. The printed circuit board with embedded electronic components, as set forth in any of claims 1 to 3, wherein the electronic components are passive elements and/or active elements.

6. A method of fabricating a printed circuit board with embedded electronic components having outer electrodes, comprising:
(a) forming insertion holes for containing the electronic components on a substrate;
(b) inserting and securing the electronic components in the insertion holes;
(c) filling the gaps between the insertion holes and the electronic components;
(d) forming an attachment layer in contact with the electrode on at least one surface of the substrate; and
(e) forming circuits on the attachment layer.

7. The method as set forth in claim 6, wherein the inserting of the electronic components (operation b) comprises attaching an adhesion sheet on a surface of the substrate to secure the electronic components.

8. The method as set forth in claim 6, wherein the inserting of the electronic components (operation b) comprises using adhesion ink to secure the electronic components.

9. The method as set forth in either of claim 7 or 8, wherein the adhesion sheet or adhesion ink is formed of a material that loses its adhesion with heat or UV radiation.

10. The method as set forth in claim 6, wherein the forming of the insertion holes (operation a) comprises a desmearing process of removing smears that occur during the forming of the insertion holes.

11. The method as set forth in claim 6, wherein the filling of the gaps (operation c) is performed by means of a vacuum printer.

12. The method as set forth in claim 6, wherein the substrate is a copper clad laminate.

13. The method as set forth in claim 6, wherein the electronic components are passive elements and/or active elements.
